(19) United States
(12) Patent Application Publication
(10) Pub. No.: US 2011/0228998 A1
(43) Pub. Date: Sep. 22, 2011

(54) SYSTEM AND METHOD FOR AUTOMATIC COMPUTATION OF MR IMAGING SCAN PARAMETERS

(76) Inventors: Vivek Prabhakar Vaidya, Bangalore (IN); Xiaodong Tao, Niskayuna, NY (US); Robert David Darrow, Scotia, NY (US); Rakesh Mullick, Bangalore (IN); Maggie Mei-Kei Fung, Waukesha, WI (US); Thomas Kwok-Fah Foo, Clifton Park, NY (US); Kenji Suzuki, Hino-shi (JP); Sandeep Narendra Gupta, Clifton Park, NY (US); Ting Song, Rockville, MD (US)

(21) Appl. No.: 12/726,509

(22) Filed: Mar. 18, 2010

(51) Int. Cl. G06K 9/00; G01R 33/48

(52) U.S. Cl. 382/131; 324/309

(57) ABSTRACT

A system and method for automatic computation of MR imaging scan parameters include a computer programmed to acquire a first set of MR data from an imaging subject, the first set of MR data comprising a plurality of slices acquired at a first field-of-view. The computer is also programmed to reconstruct the plurality of slices into a plurality of localizer images and identify a 3D object based on the plurality of localizer images. The computer is further programmed to prescribe a scan, execute the prescribed scan to acquire a second set of MR data, and reconstruct the second set of MR data into an image. The prescribed scan includes one of a reduced field-of-view based on a boundary of the 3D object and a shim region based on the boundary of the 3D object.

### BACKGROUND OF THE INVENTION

Embodiments of the invention relate generally to MR imaging and, more particularly, to automatically determining scan parameters of an MR scan.

When a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, or “longitudinal magnetization”, M_{Z}, may be rotated, or “tipped”, into the x-y plane to produce a net transverse magnetic moment Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received NMR signals are digitized and processed to reconstruct the image using one of many well-known reconstruction techniques.

Conventional techniques for MR imaging include prescribing imaging scans configured to acquire MR imaging data from a field-of-view (FOV) of an imaging subject or object. It may be beneficial to also prescribe shimming parameters for a specific region of the object within the FOV. Often, the technologist operating an MR scanner is required to specify or defining the FOV and/or shim regions manually. For example for a cardiac MR scan, by shimming over only the heart rather than the entire upper torso, the magnetic field homogeneity is significantly improved compared to attempting to correct the shim over the entire upper torso. (Note that an operation to correct for the magnetic field inhomogeneity is known as correcting the magnet shim.

This operation involves spatially mapping the magnetic (Bₒ) field and computing the necessary components of the magnetic field, say in the spherical coordinate frame (i.e., spherical harmonics components) and applying the necessary currents to shim coils that generate the corresponding spherical harmonic magnetic field components.) Accordingly, it is important that the technologist be trained in defining FOV and shim regions for specific anatomy. Experienced technologists, however, may be difficult to find in emerging markets. Consequently, MR scans performed by less experienced technologists may suffer in image quality or have compromised diagnostic information. In addition, general technologists may not have extensive experience when dealing with less common anatomical regions. Thus, they may either take too long to perform these types of scans or would have scans with poor or inconsistent image quality.

Defining the FOV and/or shim regions manually may include, for example, tracing the boundary of the desired FOV or shim region on an anatomical image. Such manual tracing, however, may be subject to MRI artifacts on the periphery of the scan or may include challenges in finding the precise boundary of parts of the body in the case of noisy images.

In addition to manually defining the FOV and/or shim regions, well-trained technologists operating the MR scanner are often required to set up and prepare the imaging patient for imaging. Such setup may include landmarking the patient within the MR scanner by manually positioning the patient on the scanner table, then manually positioning the table so that a region of interest of the patient coincides with scanner alignment lights or markers.

It would therefore be desirable to have a system and method capable of automating setup and scanning parameters for MR imaging.

### BRIEF DESCRIPTION OF THE INVENTION

In accordance with one aspect of the invention, an MRI apparatus includes an MRI system having a plurality of gradient coils positioned about a bore of a magnet to impress a polarizing magnetic field. An RF transceiver system and an RF switch are controlled by a pulse module to transmit and receive RF signals to and from an RF coil assembly to acquire MR images. The MRI apparatus also includes a computer programmed to acquire a first set of MR data from an imaging subject, the first set of MR data comprising a plurality of slices acquired at a first field-of-view. The computer is also programmed to reconstruct the plurality of slices into a plurality of localizer images and identify a 3D object based on the plurality of localizer images. The computer is further programmed to prescribe a scan, execute the prescribed scan to acquire a second set of MR data, and reconstruct the second set of MR data into an image. The prescribed scan includes one of a reduced field-of-view based on a boundary of the 3D object and a shim region based on the boundary of the 3D object.

In accordance with another aspect of the invention, a method includes acquiring a plurality of localizer MR data at a first field-of-view from an imaging subject, reconstructing a plurality of slices of the plurality of localizer MR data into a first plurality of images, and generating a 3D object of a portion of the imaging subject based on the first plurality of images. The method also includes generating a scan prescription configured to one of acquire MR imaging data of the 3D object via a second field-of-view determined based on a boundary of the 3D object, wherein the second field-of-view is smaller than the first field-of-view, and acquire MR imaging data of the 3D object via a shim region determined based on the boundary of the 3D object. A scan based on the scan prescription is executed to acquire the MR imaging data, and an anatomical image is reconstructed from the acquired MR imaging data. The anatomical image is displayed to a user.

In accordance with yet another aspect of the invention, the invention is embodied in a computer program stored on a computer readable storage medium and having instructions which, when executed by a computer, cause the computer to prescribe a localizer scan configured to acquire a plurality of slices of MR imaging data from an imaging subject at a first field-of-view, execute the prescribed localizer scan, and reconstruct the MR imaging data into a plurality of localizer images. The instructions also cause the computer to generate a 3D object based on the plurality of localizer images and identify a region having a boundary encompassing at least a portion of the 3D object, wherein the boundary is less than a boundary of the first field-of-view. A non-localizer scan comprising MR data acquisition of the portion of the 3D object is caused to be executed, wherein the region comprises one of a second field-of-view for the non-localizer scan and a shim area for the non-localizer scan. The instructions further cause the computer to reconstruct MR data acquired during execution of the non-localizer scan into an anatomical image and display the anatomical image to a user.

Various other features and advantages will be made apparent from the following detailed description and the drawings.

### BRIEF DESCRIPTION OF THE DRAWINGS

The drawings illustrate embodiments presently contemplated for carrying out the invention.

In the drawings:

FIG. 1 is a schematic block diagram of an MR imaging system incorporating the invention.

FIG. 2 is a flowchart illustrating a technique for preparing and executing an MR imaging scan having an FOV region or a shim region automatically determined according to an embodiment of the invention.

FIG. 3 is a flowchart illustrating steps for identifying a 3D model for a process of technique of FIG. 2 according to an embodiment of the invention.

FIG. 4 is a flowchart illustrating steps for identifying a 3D model for a process of technique of FIG. 2 according to another embodiment of the invention.

FIG. 5 is a flowchart illustrating steps for identifying an FOV boundary for a process of technique of FIG. 2 according to another embodiment of the invention.

FIG. 6 is a flowchart illustrating steps for identifying a shim boundary for a process of technique of FIG. 2 according to another embodiment of the invention.

FIG. 7 is a schematic diagram showing an embodiment of a step of the flowchart of FIG. 5 according to an embodiment of the invention.

FIG. 8 is a flowchart illustrating a technique for localizing an object within a scanner according to an embodiment of the invention.

### DETAILED DESCRIPTION

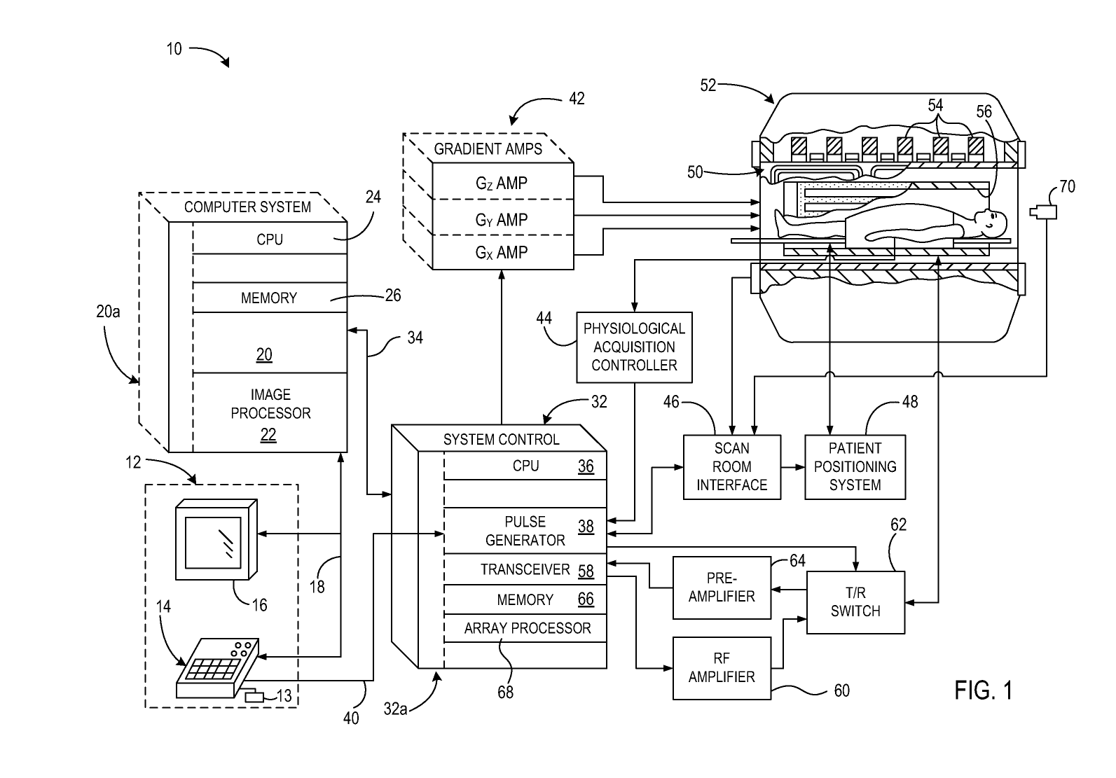

Referring to FIG. 1, the major components of a magnetic resonance imaging (MRI) system 10 incorporating an embodiment of the invention are shown. The operation of the system is controlled from an operator console 12 which includes a keyboard or other input device 13, a control panel 14, and a display screen 16. The console 12 communicates through a link 18 with a separate computer system 20 that enables an operator to control the production and display of images on the display screen 16. The computer system 20 includes a number of modules which communicate with each other through a backplane 20a. These include an image processor module 22, a CPU module 24 and a memory module 26, known in the art as a frame buffer for storing image data arrays. The computer system 20 communicates with a separate system control 32 through a high speed serial link 34. The input device 13 can include a mouse, joystick, keyboard, track ball, touch activated screen, light wand, voice control, or any similar or equivalent input device, and may be used for interactive geometry prescription.

The system control 32 includes a set of modules connected together by a backplane 32a. These include a CPU module 36 and a pulse generator module 38 which connects to the operator console 12 through a serial link 40. It is through link 40 that the system control 32 receives commands from the operator to indicate the scan sequence that is to be performed. The pulse generator module 38 operates the system components to carry out the desired scan sequence and produces data which indicates the timing, strength and shape of the RF pulses produced, and the timing and length of the data acquisition window. The pulse generator module 38 connects to a set of gradient amplifiers 42, to indicate the timing and shape of the gradient pulses that are produced during the scan. The pulse generator module 38 can also receive patient data from a physiological acquisition controller 44 that receives signals from a number of different sensors connected to the patient, such as ECG signals from electrodes attached to the patient. And finally, the pulse generator module 38 connects to a scan room interface circuit 46 which receives signals from various sensors associated with the condition of the patient and the magnet system. It is also through the scan room interface circuit 46 that a patient positioning system 48 receives commands to move the patient to the desired position for the scan.

The gradient waveforms produced by the pulse generator module 38 are applied to the gradient amplifier system 42 having Gx, Gy, and Gz amplifiers. Each gradient amplifier excites a corresponding physical gradient coil in a gradient coil assembly generally designated 50 to produce the magnetic field gradients used for spatially encoding acquired signals. The gradient coil assembly 50 forms part of a magnet assembly 52 which includes a polarizing magnet 54 and a whole-body RF coil 56. A transceiver module 58 in the system control 32 produces pulses which are amplified by an RF amplifier 60 and coupled to the RF coil 56 by a transmit/receive switch 62. The resulting signals emitted by the excited nuclei in the patient may be sensed by the same RF coil 56 and coupled through the transmit/receive switch 62 to a preamplifier 64. The amplified MR signals are demodulated, filtered, and digitized in the receiver section of the transceiver 58. The transmit/receive switch 62 is controlled by a signal from the pulse generator module 38 to electrically connect the RF amplifier 60 to the coil 56 during the transmit mode and to connect the preamplifier 64 to the coil 56 during the receive mode. The transmit/receive switch 62 can also enable a separate RF coil (for example, a surface coil) to be used in either the transmit or receive mode.

The MR signals picked up by the RF coil 56 are digitized by the transceiver module 58 and transferred to a memory module 66 in the system control 32. A scan is complete when an array of raw k-space data has been acquired in the memory module 66. This raw k-space data is rearranged into separate k-space data arrays for each image to be reconstructed, and each of these is input to an array processor 68 which operates to Fourier transform the data into an array of image data. This image data is conveyed through the serial link 34 to the computer system 20 where it is stored in memory. In response to commands received from the operator console 12, this image data may be archived in long term storage or it may be further processed by the image processor 22 and conveyed to the operator console 12 and presented on the display 16.

MRI system 10 includes an optical imaging device or camera 70 coupled to scan room interface circuit 46. Camera 70 may be configured to capture still images such as photographs or to capture moving images such as video. In one embodiment, camera 70 is a closed circuit television camera. Using images captured via camera 70, MRI system 10 may automatically landmark a patient positioned therein to determine, for example, the location of the patient with respect to magnet assembly 52 or the orientation of the patient such as, for example, whether the patient is positioned head first or feet first or whether the patient is in a supine or prone position. These and other examples of automatic patient landmarking will be described below with respect to FIG. 8.

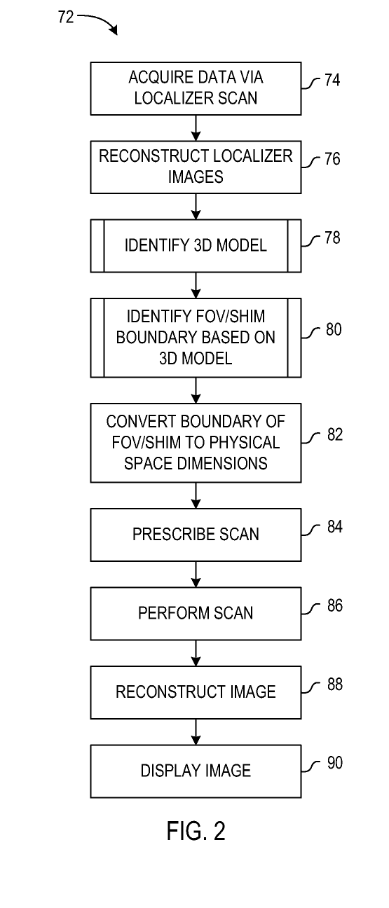

FIG. 2 shows a flowchart illustrating a technique 72 for preparing and executing an MR imaging scan according to an embodiment of the invention. Technique 72 includes steps for automatically calculating or defining one or more scanning parameters or elements of the MR scan to reduce or eliminate user involvement during the scan or the preparation thereof

Technique 72 begins at block 74, which acquires MR data via an MR scan. In one embodiment, the MR scan is a localizer scan configured to acquire low or high resolution imaging data. It is contemplated that the imaging data acquired via the localizer scan may be any kind of MR data useful for localizing anatomical regions of interest. In one embodiment, a plurality of MR data sets are acquired that correspond to respective slices of MR data acquired of a tissue or organ of interest. The plurality of MR data sets preferably contain MR data of a complete volume of the tissue/organ. The imaging data is volumetric in nature and can comprise of either a stack of two-dimensional slices or three-dimensional volumes. The imaging data acquired via the localizer scan is reconstructed into one or more images at block 76. For example, an image may be reconstructed for each slice of acquired MR data.

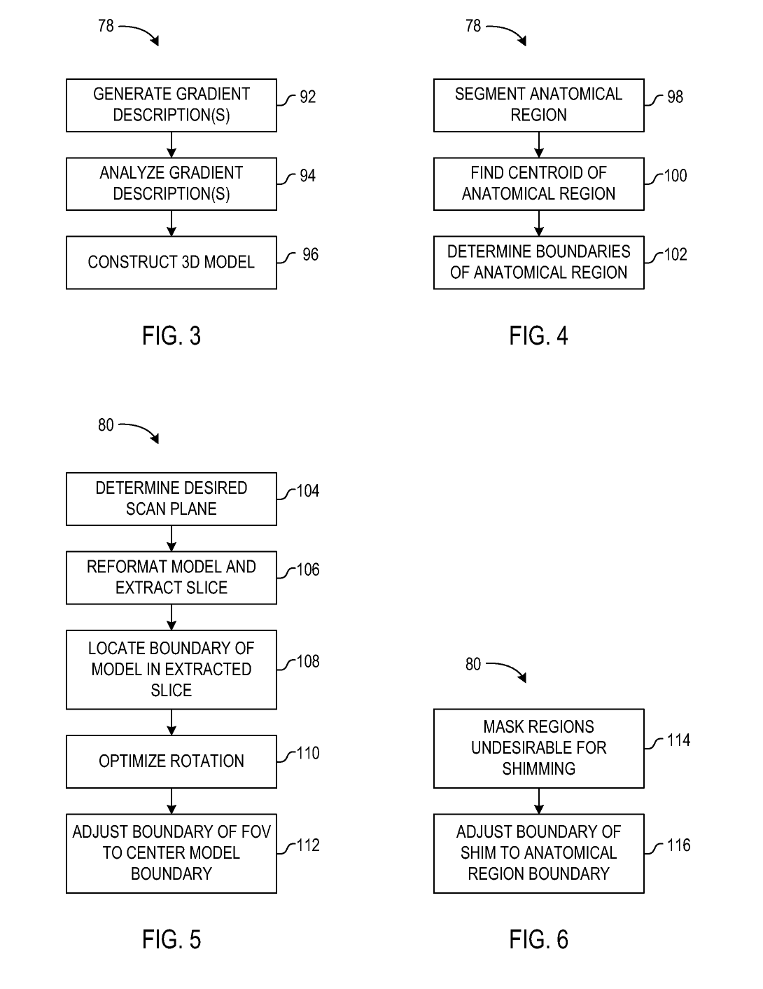

At block 78, a process block is shown for identifying a three-dimensional (3D) model of an object or tissue of interest. Referring to FIGS. 3 and 4, embodiments contemplated for carrying out identification of the 3D model at block 78 are shown. As illustrated in FIG. 3, identification of the 3D model includes, at block 92, generating a gradient description of the images reconstructed at block 76 of technique 72. The gradient descriptions of the images are analyzed at block 94 to determine or find areas of high gradient changes indicative of tissue changes. For example, in images of a cardiac region, areas of high gradient changes may indicate a tissue/air interface between the heart and the lungs of a patient. Other types of interfaces between tissues, organs, and other anatomical features of the patient are also determinable in the gradient description of the images. A 3D model of the tissue/organ may be constructed at block 96 based on the analyzed images of the complete volume of the tissue/organ.

As illustrated in FIG. 4, identification of the 3D model includes, at block 98, segmenting an anatomical region of the tissue/organ in each of the images reconstructed at block 76 of technique 72 to isolate the region of the tissue/organ from other regions in the images. In one embodiment, segmenting the tissue/organ of interest from other tissues/organs in the images includes applying a mask to the regions of the images surrounding the tissue/organ of interest. At block 100, a centroid of the unmasked regions of the images is found or determined. Using the masks and centroid, the physical delimitation or boundary of the anatomical region of interest is determined at block 102.

Referring again to FIG. 2, a process block is shown at block 80 for identifying a field-of-view (FOV) boundary or a shim boundary of the object or tissue of interest based on the 3D model determined at block 78. Referring to FIGS. 5 and 6, embodiments contemplated for carrying out identification of the FOV/shim boundaries at block 80 are shown. As illustrated in FIG. 5, identification of an FOV boundary includes determining a desired scan plane at block 104. In one embodiment, the desired scan plane may be input by a user or may be automatically determined by the scanner. The desired scan plane represents the imaging plane for acquiring MR data of the tissue/organ in a subsequent scan. The subsequent scan, in one example, may be performed to acquire a higher resolution of imaging data of the tissue/organ along the desired scan plane or to apply an imaging scan sequence to the tissue/organ along the desired scan plane that is different from the scan plane of the imaging scan sequence performed at block 74 of technique 72. At block 106, the model is reformatted along a vector/rotation matrix, and a slice of the model is extracted therefrom along the desired scan plane.

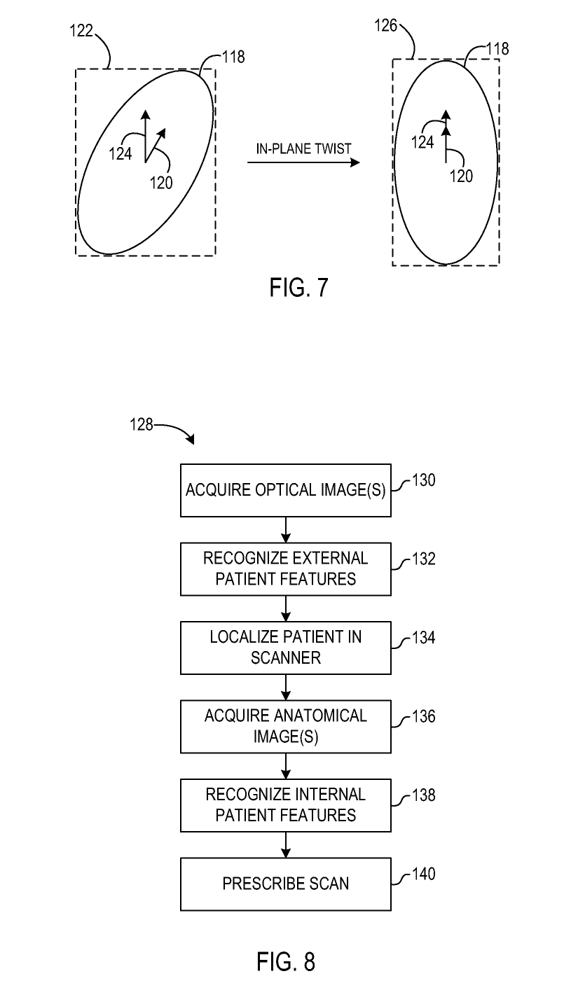

Still referring to FIG. 5, the extracted slice is analyzed at block 108 to locate a boundary of the model along the extracted slice. The boundary of the model may be rotated to optimize its rotation at block 110. For example, the rotation of the object along the extracted slice may result in wrapping artifacts for a given FOV size or may result in a non-optimal, larger FOV. Performing an in-plane twist to the object in the extracted slice helps to align the object to a rectangular FOV and to reduce the amount of non-object data acquired during an MR scan. For example, FIG. 7 shows a model boundary 118 along a first orientation 120 and a bounding box 122 along a second orientation 124 fit to model boundary 118. Re-orienting model boundary 118 and first orientation 120 along second orientation 124 via an in-plane twist results in a bounding box 126, which is fit to re-oriented model boundary 118, that has a reduced area as compared with bounding box 122. Accordingly, data acquisition outside the boundary of the 3D model is minimized.

Referring again to FIG. 5, the boundary of the FOV is adjusted at block 112 to center the model boundary therein. The FOV boundary is adjusted to closely crop the model boundary while avoiding the potential for wrapping artifacts in the data acquired of the FOV. The FOV boundary is thus smaller than or reduced as compared with the boundary of the FOV used to acquire the MR data at block 74 of technique 72.

As illustrated in FIG. 6, identification of a shim boundary corresponding to block 80 of technique 72 includes masking regions from the 3D model that are undesirable for shimming at block 114. For example, for cardiac scanning, it may be desirable to remove high intensity regions of a torso such as chest wall fat from the shimming region. At block 116, a shim boundary is adjusted to encompass the boundary of the anatomical region or object of interest.

Referring back to technique 72 of FIG. 2, the boundary of the FOV or shim region identified at block 80 is converted to physical space dimensions at block 82. A scan based on the physical space dimensions of the boundary of the FOV or shim region is prescribed at block 84, and the prescribed scan is performed or executed at block 86 to acquire MR data from the 3D model. At block 88, the acquired MR data is reconstructed into an image, which may be displayed to a user at block 90.

Embodiments of the invention include automatically determining the FOV boundary without automatically determining the shim boundary, automatically determining the shim boundary without automatically determining the FOV boundary, and automatically determining both the FOV boundary and the shim boundary. Execution of the scan at block 86 thus includes performing a scan having the FOV boundary automatically determined, the shim boundary automatically determined, or both the FOV boundary and the shim boundary automatically determined.

FIG. 8 shows a flowchart illustrating a technique 128 for landmarking an imaging subject or patient within an MRI system according to an embodiment of the invention. Technique 128 may be executed by a computer such as computer 20 of FIG. 1. Technique 128 begins at block 130 by acquiring one or more optical images of a patient on a patient table of an MRI system such as MRI system 10 shown in FIG. 1. Optical images may be acquired, for example, via camera 70 after the patient has been positioned on the patient table. Technique 128 includes recognizing external patient features at block 132. For example, facial recognition algorithms may be executed to locate the tip of the nose or the corners of the eyes. Other recognition algorithms may be executed to identify other parts or features of the patient. In addition to recognizing particular features of the patient, the recognition algorithms may be executed to determine a size or an orientation of the features. For example, a height and a weight of the patient may be recognized in the optical images. In another example, the orientation of the patient may be determined to indicate whether the patient is positioned head first or feet first or whether the patient is in a supine or prone position. This process describes a manner in which several time-consuming and manual steps conducted by a technologist are replaced by an automated process wherein the patient is placed on the scan table, made comfortable, and the scanning process automatically proceeds when the technologist initiates the examination (via a button push in one embodiment). This process automatically determines the patient orientation, patient weight, region of the anatomy in the imaging field-of-view, appropriate phased array element coil selection (based on the anatomy to be scanned or the imaging field-of-view), and also translates the table to a location such that the anatomy to be scanned is in the isocenter of the MR magnet.

Using the recognized features, the patient may be localized within the MRI system or scanner at block 134. The patient's position on the patient table may be determined to help the scanner position the patient within the magnet assembly. For example, based on a position of the patient table and based on a recognized feature of the patient in relation to the table position, the position of the patient on the table may be determined. Based on the determined patient position, a scan prescription of a target anatomy of interest within the patient may include a table motion distance that places the anatomy of interest at a predetermined position within the scanner.

At block 136, one or more anatomical images of a patient may be acquired. In one embodiment, the MRI system may acquire and reconstruct real-time anatomical images of the patient such as via a low-quality localizer imaging scan sequence. In another embodiment, anatomical images may be acquired from an image storage location. It is contemplated that the anatomical images acquired from an image storage location may be anatomical images acquired and reconstructed using an image scanner having a different modality than the MRI system. For example, anatomical images acquired via ultrasound, x-ray, CT, or the like imaging modalities are contemplated. It is further contemplated that the anatomical images may be a reference image of a different subject or an abstract atlas serving as a reference.

The anatomical images are analyzed at block 138 to recognize internal patient features. That is, internal landmarks of the patient may be recognized to assist in prescribing image scans. For example, for a cardiac study, the anatomical image(s) may be analyzed to locate the apex of the heart. An analysis of the internal landmarks of the patient in the anatomical image(s) may additionally help to determine a size or an orientation of the patient within the scanner.

Based on the recognized external and/or internal features of the patient and on the localization of the patient in the scanner, an MRI scan may be prescribed at block 140. It is contemplated that the prescribed scan may be based on any number of a combination of recognized features of the patient. For example, the recognized features may include an estimated size and/or weight of the patient or of the patient's internal anatomy or may include a location of the patient's external or internal features. These scan parameters may be thus prescribed to be tailored to fit the patient habitus and are preferably optimized for scan range, field of view, imaging resolution, dose of contrast, imaging time, spatial resolution, or the like, for example.

In addition to acquiring optical or anatomical images for assisting with scan prescriptions, the optical and/or anatomical images may also be used to automatically determine the spatial extent of respiratory motion and to also provide an automatic indication of the suspension of respiration during a breath-hold process. For example, a patient's maximum breath-hold capability (or maximum time patient is able to hold his/her breath) may be determined automatically. The optical or anatomical images may also be used to automatically determine if anatomy being imaged underwent unexpected motion or to detect patient conditions that may trigger an early termination to the scan.

The above-described methods describe scans for a single location. However, the methodology is equally applicable when the entire body is being scanned in a whole-body imaging scan. Here, the initial location of the patient is determined via the technique shown in FIG. 8, and the type of scans, imaging parameters, and coil choices may be determined for multiple locations by repeating techniques described previously and illustrated in FIGS. 2-7 for each location. In this manner, the multiple locations may encompass the entire body or a majority thereof.

The above-described methods can be embodied in the form of computer program code containing instructions embodied in one or more tangible computer readable storage media, such as floppy diskettes and other magnetic storage media, CD ROMs and other optical storage media, flash memory and other solid-state storage devices, hard drives, or any other computer-readable storage medium, wherein, when the computer program code is loaded into and executed by a computer, the computer becomes an apparatus for practicing the disclosed method.

A technical contribution for the disclosed method and apparatus is that is provides for a computer implemented automatic determination of scan parameters of an MR scan such as an automatically determined field-of-view region or an automatically determined shim region.

In accordance with one embodiment of the invention, an MRI apparatus includes an MRI system having a plurality of gradient coils positioned about a bore of a magnet to impress a polarizing magnetic field. An RF transceiver system and an RF switch are controlled by a pulse module to transmit and receive RF signals to and from an RF coil assembly to acquire MR images. The MRI apparatus also includes a computer programmed to acquire a first set of MR data from an imaging subject, the first set of MR data comprising a plurality of slices acquired at a first field-of-view. The computer is also programmed to reconstruct the plurality of slices into a plurality of localizer images and identify a 3D object based on the plurality of localizer images. The computer is further programmed to prescribe a scan, execute the prescribed scan to acquire a second set of MR data, and reconstruct the second set of MR data into an image. The prescribed scan includes one of a reduced field-of-view based on a boundary of the 3D object and a shim region based on the boundary of the 3D object.

In accordance with another embodiment of the invention, a method includes acquiring a plurality of localizer MR data at a first field-of-view from an imaging subject, reconstructing a plurality of slices of the plurality of localizer MR data into a first plurality of images, and generating a 3D object of a portion of the imaging subject based on the first plurality of images. The method also includes generating a scan prescription configured to one of acquire MR imaging data of the 3D object via a second field-of-view determined based on a boundary of the 3D object, wherein the second field-of-view is smaller than the first field-of-view, and acquire MR imaging data of the 3D object via a shim region determined based on the boundary of the 3D object. A scan based on the scan prescription is executed to acquire the MR imaging data, and an anatomical image is reconstructed from the acquired MR imaging data. The anatomical image is displayed to a user.

In accordance with yet another embodiment of the invention, the invention is embodied in a computer program stored on a computer readable storage medium and having instructions which, when executed by a computer, cause the computer to prescribe a localizer scan configured to acquire a plurality of slices of MR imaging data from an imaging subject at a first field-of-view, execute the prescribed localizer scan, and reconstruct the MR imaging data into a plurality of localizer images. The instructions also cause the computer to generate a 3D object based on the plurality of localizer images and identify a region having a boundary encompassing at least a portion of the 3D object, wherein the boundary is less than a boundary of the first field-of-view. A non-localizer scan comprising MR data acquisition of the portion of the 3D object is caused to be executed, wherein the region comprises one of a second field-of-view for the non-localizer scan and a shim area for the non-localizer scan. The instructions further cause the computer to reconstruct MR data acquired during execution of the non-localizer scan into an anatomical image and display the anatomical image to a user.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An MRI apparatus comprising:
a magnetic resonance imaging (MRI) system having a plurality of gradient coils positioned about a bore of a magnet, and an RF transceiver system and an RF switch controlled by a pulse module to transmit RF signals to and from an RF coil assembly to acquire MR images; and
a computer programmed to:
acquire a first set of MR data from an imaging subject, the first set of MR data comprising a plurality of slices acquired at a first field-of-view;
reconstruct the plurality of slices into a plurality of localizer images;
identify a 3D object based on the plurality of localizer images;
prescribe a scan comprising one of:
a reduced field-of-view based on a boundary of the 3D object; and
a shim region based on the boundary of the 3D object;
execute the prescribed scan to acquire a second set of MR data; and
reconstruct the second set of MR data into an image.

2. The MRI apparatus of claim 1 wherein the computer, in being programmed to identify the 3D object, is programmed to:
generate a gradient description for each of the plurality of localizer images;
identify high gradient changes in the plurality of localizer images; and
construct a 3D model of the object based on the high gradient changes.

3. The MRI apparatus of claim 2 wherein the computer is further programmed to:
locate a boundary of the 3D model along a scan plane of interest; and
generate a boundary of the reduced field-of-view to encompass the boundary of the 3D model.

4. The MRI apparatus of claim 3 wherein the computer is further programmed to receive a user input identifying the scan plane of interest.

5. The MRI apparatus of claim 3 wherein the computer is further programmed to optimize a rotation of the 3D model boundary within the scan plane of interest to minimize acquisition of data outside the 3D model boundary.

6. The MRI apparatus of claim 1 wherein the computer, in being programmed to identify the 3D object, is programmed to:
apply a mask to each of the plurality of localizer images to segment an object of interest;
locate a centroid of the object of interest; and
determine a 3D boundary of the object of interest.

7. The MRI apparatus of claim 6 wherein the computer is further programmed to generate the shim region to encompass the 3D boundary.

8. The MRI apparatus of claim 7 wherein the computer is further programmed to mask at least one region of the object of interest to be outside the shim region.

9. The MRI apparatus of claim 8 wherein the computer, in being programmed to mask at least one anatomical feature near the shim region that is not of interest.

10. The MRI apparatus of claim 1 further comprising an optical camera configured to acquire visual images of the imaging subject; and
wherein the computer is further configured to determine scanning parameters of the imaging subject using visual images acquired by the optical camera.

11. The MRI apparatus of claim 10 wherein the computer, in being programmed to determine scanning parameters of the imaging subject, is configured to one of:
determine a position of the imaging subject with respect to the MRI system;
determine an orientation of the imaging subject with respect to the MRI system;
estimate a size and a weight of the imaging subject;
identify an anatomy of the imaging subject;
identify a size of the anatomy;
determine a number of receiver coil elements based on an imaging field-of-view;
determine a respiratory motion of the imaging subject; and
determine a motion of the imaging subject during scanning

12. The MRI apparatus of claim 10 wherein the optical camera is a closed circuit television camera.

13. A method comprising:
acquiring a plurality of localizer MR data at a first field-of-view from an imaging subject;
reconstructing a plurality of slices of the plurality of localizer MR data into a first plurality of images;
generating a 3D object of a portion of the imaging subject based on the first plurality of images;
generating a scan prescription configured to one of:
acquire MR imaging data of the 3D object via a second field-of-view determined based on a boundary of the 3D object, wherein the second field-of-view is smaller than the first field-of-view; and
acquire MR imaging data of the 3D object via a shim region determined based on the boundary of the 3D object;
executing a scan based on the scan prescription to acquire the MR imaging data;
reconstructing an anatomical image from the acquired MR imaging data; and
displaying the anatomical image to a user.

14. The method of claim 13 wherein generating the scan prescription comprises generating the scan prescription configured to acquire the MR imaging data of the 3D object via a combination of the second field-of-view and the shim region.

15. The method of claim 13 wherein generating the 3D object comprises:
generating a gradient description for each of the first plurality of images;
identifying regions of high gradient changes about an object of interest in the first plurality of images; and
generating a 3D model of the object based on the high gradient changes; and
wherein generating the scan prescription comprises:
identifying a boundary of the 3D model along a scan plane of interest; and
generating a boundary of the second field-of-view to maximize a size of the boundary of the 3D model along the scan plane of interest within the second field-of-view.

16. The method of claim 13 wherein generating the 3D object comprises:
segmenting an object of interest in each of the first plurality of images from other objects not of interest;
locate a centroid of the object of interest; and
determine a 3D boundary of the object of interest; and
wherein generating the scan prescription comprises generating a boundary of the shim region based on the 3D boundary of the object of interest.

17. The method of claim 13 further comprising:
acquiring an optical image of the imaging subject;
automatically localizing a first object parameter based on the optical image, the first object parameter comprising one of a size and an orientation of a first portion of the imaging subject;
automatically localizing a second object parameter based on the first plurality of images, the second object parameter comprising one of a size and an orientation of a second portion of the imaging subject; and
wherein generating the scan prescription comprises automatically generating scan parameters based on one of the automatically localized first and second object parameters.

18. A computer readable storage medium having stored thereon a computer program comprising instructions, which, when executed by a computer, cause the computer to:
(A) prescribe a localizer scan configured to acquire a plurality of slices of MR imaging data from an imaging subject at a first field-of-view;
(B) execute the prescribed localizer scan;
(C) reconstruct the MR imaging data into a plurality of localizer images;
(D) generate a 3D object based on the plurality of localizer images;
(E) identify a region having a boundary encompassing at least a portion of the 3D object, wherein the boundary is less than a boundary of the first field-of-view;
(F) execute a non-localizer scan comprising MR data acquisition of the portion of the 3D object, wherein the region comprises one of a second field-of-view for the non-localizer scan and a shim area for the non-localizer scan;
(G) reconstruct MR data acquired during execution of the non-localizer scan into an anatomical image; and
(H) display the anatomical image to a user.

19. The computer readable storage medium of claim 18 wherein the instructions that cause the computer to generate the 3D object cause the computer to:
identify areas of high gradient changes about an object of interest in the plurality of localizer images; and
construct a 3D model of the object based on the high gradient changes; and
wherein the instructions further cause the computer to:
determine a scan plane of interest;
identify a boundary of the 3D model along the scan plane of interest;
generate the boundary of the region about the boundary of the 3D model such that the boundary of the region is positioned adjacently to the boundary of the 3D model; and
prescribe the non-localizer scan based on the generated boundary of the region, wherein the region comprises the second field-of-view for the non-localizer scan.

20. The computer readable storage medium of claim 18 wherein the instructions that cause the computer to generate the 3D object cause the computer to:
mask an area in the plurality of localizer images outside of an object of interest;
determine a 3D boundary of the object of interest based on an unmasked area in the plurality of localizer images; and
locate a centroid of the object of interest; and
wherein the instructions further cause the computer to:
generate the boundary of the region about the 3D boundary of the object of interest such that the boundary of the region is positioned adjacently to the 3D boundary of the object of interest; and
prescribe the non-localizer scan based on the generated boundary of the region, wherein the region comprises the shim area for the non-localizer scan.

21. The method of claim 18 wherein the instructions further cause the computer to repeat (A)-(H) for each of a plurality of locations in the imaging subject according to a whole-body imaging scan.
